(19) United States
(12) Patent Application Publication
(10) Pub. No.: US 2013/0215370 A1
(43) Pub. Date: Aug. 22, 2013

(54) DISPLAY DEVICE SUBSTRATE, METHOD FOR PRODUCING THE SAME, AND DISPLAY DEVICE

(71) Applicants: Yudai Takanishi, Osaka-shi (JP); Yohsuke Kanzaki, Osaka-shi (JP); Tetsuya Okamoto, Osaka-shi (JP); Yuhichi Saitoh, Osaka-shi (JP); Yoshiki Nakatani, Osaka-shi (JP)

(72) Inventors: Yudai Takanishi, Osaka-shi (JP); Yohsuke Kanzaki, Osaka-shi (JP); Tetsuya Okamoto, Osaka-shi (JP); Yuhichi Saitoh, Osaka-shi (JP); Yoshiki Nakatani, Osaka-shi (JP)

(73) Assignee: Sharp Kabushiki Kaisha, Osaka-shi Osaka (JP)

(21) Appl. No.: 13/817,246

(22) PCT Filed: May 11, 2011
(86) PCT No.: PCT/JP2011/002634

§ 371 Date: Mar. 1, 2013

(30) Foreign Application Priority Data
Aug. 18, 2010 (JP) 2010-183225

(51) Int. Cl. G02F 1/1362; H01L 33/00

(52) U.S. Cl. CPC G02F 1/136227; H01L 33/0041
USPC 349/139; 257/99; 438/22

(57) ABSTRACT

A thin film transistor substrate (20) includes: an insulating substrate (10a); a gate insulating layer (12) provided on the insulating substrate (10a); a connection layer (25) provided on the gate insulating layer (12), and made of indium gallium zinc oxide (IGZO); a drain electrode (16b) provided on the connection layer (25), and made of titanium; a contact hole (Ca) formed in the connection layer (25) and the drain electrode (16b); and a pixel electrode (19a) provided on a surface of the contact hole (Ca), and contacting the connection layer (25). The drain electrode (16b) and the pixel electrode (19a) are electrically connected together through the connection layer (25).

### TECHNICAL FIELD

The present invention generally relates to substrates for display devices (hereinafter referred to as “display device substrates”), and more particularly to display device substrates including semiconductor layers made of oxide semiconductors, methods for fabricating such substrates, and display devices.

### BACKGROUND ART

In a thin film transistor substrate (active matrix substrate), a thin film transistor (hereinafter referred to as a “TFT”) is provided as a switching device in each of the pixels, which are minimum units of an image.

In the thin film transistor substrate, a thin film transistor using semiconductor layers of amorphous silicon is generally used as a switching device of each of the pixels, which are minimum units of an image.

A typical bottom gate-type TFT includes, e.g., a gate electrode provided on an insulating substrate, a gate insulating layer provided to cover the gate electrode, an island-shaped semiconductor layer provided on the gate insulating layer to overlap the gate electrode, and a source electrode and a drain electrode provided on the semiconductor layer to face each other.

In the bottom gate-type TFT, the upper part of a channel region of the semiconductor layer is covered with an interlayer insulating film made of SiO₂ etc., and the surface of an interlayer insulating film is covered with a planarization film made of an acrylic resin etc. A pixel electrode made of indium tin oxide (ITO) is formed on the planarization film, and the drain electrode is connected to the pixel electrode through a contact hole formed in a multilayer film of the interlayer insulating film and the planarization film.

The pixel electrode is formed on the planarization film, thereby fabricating the thin film transistor substrate, and a counter substrate is provided to face the thin film transistor substrate, and a liquid crystal layer is provided between the thin film transistor substrate and the counter substrate, thereby fabricating a liquid crystal display device (for example, see Patent Document 1).

### CITATION LIST

### Patent Document

PATENT DOCUMENT 1: Japanese Patent Publication No. 2000-199917

### SUMMARY OF THE INVENTION

### Technical Problem

In the above conventional thin film transistor substrate, the drain electrode is constituted by a multilayer film of a first conductive layer made of titanium, and a second conductive layer formed on the first conductive layer and made of aluminum. The second conductive layer serves as an etching stopper layer for improving selectivity during etching of the interlayer insulating film.

However, it is difficult to connect the aluminum constituting the second conductive layer to the pixel electrode made of ITO, and therefore, a poor connection may occur between the second conductive layer and the pixel electrode, resulting in deterioration of display quality.

The first conductive layer of the drain electrode may be connected to the pixel electrode through the semiconductor layer. However, if the semiconductor layer is made of amorphous silicon, the resistance of the amorphous silicon is high, and therefore, it has been difficult to connect the pixel electrode and the first conductive layer of the drain electrode together through the amorphous silicon layer.

Accordingly, in the above conventional thin film transistor substrate, in order to avoid a poor connection between the second conductive layer and the pixel electrode, and connect the pixel electrode and the drain electrode together through the contact hole, it is necessary to etch (wet-etch) the second conductive layer to cause etching shift of the second conductive layer so that the second conductive layer is located under the interlayer insulating film, and the first conductive layer is exposed, thereby connecting the first conductive layer and the pixel electrode together. This disadvantageously causes an increase in the number of fabrication process steps.

In view of the foregoing, the present invention has been developed. It is an objective of the present invention to provide a display device substrate capable of preventing a poor connection between a pixel electrode and a drain electrode to prevent deterioration of display quality without causing an increase in the number of fabrication process steps, and a method of fabricating the display device substrate, and a display device.

### Solution to the Problem

In order to achieve the above object, a display device substrate in the present invention includes: an insulating substrate; a gate insulating layer provided on the insulating substrate; a connection layer provided on the gate insulating layer, and made of indium gallium zinc oxide; a drain electrode provided on the connection layer, and made of titanium or a metal whose standard electrode potential is lower than that of titanium; a contact hole formed in the connection layer and the drain electrode; and a pixel electrode provided on a surface of the contact hole, and contacting the connection layer, wherein the drain electrode and the pixel electrode are electrically connected together through the connection layer.

In this configuration, indium of the indium gallium zinc oxide which constitutes the connection layer is reduced by titanium which constitutes the drain electrode or a metal which constitutes the drain electrode and whose standard electrode potential is lower than that of titanium, and the resistance of the connection layer is decreased, thereby making it possible to connect the pixel electrode and the drain electrode together through the connection layer whose resistance is decreased. Therefore, unlike the above-described conventional techniques, it is unnecessary to perform an etching process for connecting the pixel electrode and the drain electrode together. As a result, it becomes possible to prevent a poor connection between the pixel electrode and the drain electrode to prevent deterioration of display quality without causing an increase in the number of fabrication process steps.

In the display device substrate of the present invention, the drain electrode may include a first conductive layer provided on a surface of the connection layer, and a second conductive layer provided on a surface of the first conductive layer, and the first conductive layer may be made of the titanium.

In this configuration, the drain electrode has a multilayer structure of the first conductive layer and the second conductive layer, and even if a poor connection occurs between the pixel electrode and the second conductive layer, the pixel electrode and the second conductive layer of the drain electrode can be connected together through the connection layer whose resistance is decreased.

A display device substrate in the present invention includes: an insulating substrate; a line provided on the insulating substrate, and formed by a gate line layer; a gate insulating layer covering the line formed by the gate line layer; a connection layer provided on the gate insulating layer, and made of indium gallium zinc oxide; a line provided on the connection layer, and formed by a source line layer made of titanium or a metal whose standard electrode potential is lower than that of titanium; a contact hole formed in the gate insulating layer, the connection layer, and the line formed by the source line layer; and a conductive film provided on a surface of the contact hole, and contacting the line formed by the gate line layer and the connection layer, wherein the line formed by the gate line layer and the line formed by the source line layer are electrically connected together through the connection layer and the conductive film.

In this configuration, indium of the indium gallium zinc oxide which constitutes the connection layer is reduced by titanium which constitutes the line formed by the source line layer or a metal which constitutes the line formed by the source line layer and whose standard electrode potential is lower than that of titanium, and the resistance of the connection layer is decreased, thereby making it possible to connect the line formed by the gate line layer and the line formed by the source line layer together through the connection layer whose resistance is decreased. Therefore, unlike the above-described conventional techniques, it is unnecessary to perform an etching process for connecting the line formed by the gate line layer and the line formed by the source line layer together. As a result, it becomes possible to prevent a poor connection between the line formed by the gate line layer and the line formed by the source line layer to prevent deterioration of display quality without causing an increase in the number of fabrication process steps.

In the display device substrate of the present invention, the line formed by the source line layer may include a first conductive layer provided on a surface of the connection layer, and a second conductive layer provided on a surface of the first conductive layer, and the first conductive layer may be made of the titanium.

In this configuration, the line formed by the source line layer has a multilayer structure of the first conductive layer and the second conductive layer, and even if a poor connection occurs between the conductive film and the second conductive layer, the line formed by the gate line layer and the second conductive layer of the line formed by the source line layer can be connected together through the connection layer whose resistance is decreased.

The display device substrate in the present invention has an outstanding advantage of preventing a poor connection between the pixel electrode and the drain electrode or a poor connection between the gate line and the source line to prevent deterioration of display quality without causing an increase in the number of fabrication process steps. Therefore, the display device substrate in the present invention can be preferably used to a display device including another display device substrate provided to face the display device substrate; and a display medium layer provided between the display device substrate and the another display device substrate. The display device in the present invention can be preferably used to a display device in which the display medium layer is a liquid crystal layer.

A method for forming a display device substrate in the present invention includes: a gate insulating layer formation step of forming a gate insulating layer on an insulating substrate; a connection layer formation step of forming, on the gate insulating layer, a connection layer made of indium gallium zinc oxide; a drain electrode formation step of forming, on the connection layer, a drain electrode made of titanium or a metal whose standard electrode potential is lower than that of titanium; a contact hole formation step of forming a contact hole in the connection layer and the drain electrode; and a pixel electrode formation step of forming a pixel electrode on a surface of the contact hole to contact the connection layer, thereby electrically connecting the drain electrode and the pixel electrode together through the connection layer.

In this configuration, indium of the indium gallium zinc oxide which constitutes the connection layer is reduced by titanium which constitutes the drain electrode or a metal which constitutes the drain electrode and whose standard electrode potential is lower than that of titanium, and the resistance of the connection layer is decreased, thereby making it possible to connect the pixel electrode and the drain electrode together through the connection layer whose resistance is decreased. Therefore, unlike the above-described conventional techniques, it is unnecessary to perform an etching process for connecting the pixel electrode and the drain electrode together. As a result, it becomes possible to prevent a poor connection between the pixel electrode and the drain electrode to prevent deterioration of display quality without causing an increase in the number of fabrication process steps.

In the method of forming the display device substrate in the present invention, in the drain electrode formation step, a first conductive layer made of titanium may be formed on a surface of the connection layer, and a second conductive layer may be formed on the first conductive layer, thereby forming the drain electrode including a multilayer film of the first conductive layer and the second conductive layer.

In this configuration, the drain electrode has the multilayer structure of the first conductive layer and the second conductive layer, and even if a poor connection occurs between the pixel electrode and the second conductive layer, the pixel electrode and the second conductive layer of the drain electrode can be connected together through the connection layer whose resistance is decreased.

A method for forming a display device substrate in the present invention includes: a line formation step of forming a line formed by a gate line layer on an insulating substrate; a gate insulating layer formation step of forming a gate insulating layer covering the line formed by the gate line layer; a connection layer formation step of forming, on the gate insulating layer, a connection layer made of indium gallium zinc oxide; another line formation step of forming, on the connection layer, a line formed by a source line layer made of titanium or a metal whose standard electrode potential is lower than that of titanium; a contact hole formation step of forming a contact hole in the gate insulating layer, the connection layer, and the line formed by the source line layer; and a conductive film formation step of forming a conductive film on a surface of the contact hole to contact the line formed by the gate line layer and the connection layer, thereby electrically connecting the line formed by the gate line layer and the line formed by the source line layer together through the connection layer and the conductive film.

In this configuration, indium of the indium gallium zinc oxide which constitutes the connection layer is reduced by titanium which constitutes the line formed by the source line layer or a metal which constitutes the line formed by the source line layer and whose standard electrode potential is lower than that of titanium, and the resistance of the connection layer is decreased, thereby making it possible to connect the line formed by the gate line layer and the line formed by the source line layer together through the connection layer whose resistance is decreased. Therefore, unlike the above-described conventional techniques, it is unnecessary to perform an etching process for connecting the line formed by the gate line layer and the line formed by the source line layer together. As a result, it becomes possible to prevent a poor connection between the line formed by the gate line layer and the line formed by the source line layer to prevent deterioration of display quality without causing an increase in the number of fabrication process steps.

In the method of forming the display device substrate in the present invention, in the another formation step, a first conductive layer made of titanium may be formed on a surface of the connection layer, and a second conductive layer may be formed on the first conductive layer, thereby forming the line formed by the source line layer including a multilayer film of the first conductive layer and the second conductive layer.

In this configuration, the source line has the multilayer structure of the first conductive layer and the second conductive layer, and even if a poor connection occurs between the conductive film and the second conductive layer, the gate line and the second conductive layer of the source line can be connected together through the connection layer whose resistance is decreased.

### Advantages of the Invention

According to the present invention, it is possible to prevent a poor connection between a pixel electrode and a drain electrode, and a poor connection between a line formed by a gate line layer and a line formed by a source line layer to prevent deterioration of display quality without causing an increase in the number of fabrication process steps.

### BRIEF DESCRIPTION OF THE DRAWINGS

FIG. 1 is a cross-sectional view of a liquid crystal display device having a thin film transistor substrate according to an embodiment of the present invention.

FIG. 2 is a plan view of the thin film transistor substrate according to the embodiment of the present invention.

FIG. 3 is an enlarged plan view illustrating a pixel area and a terminal area of the thin film transistor substrate according to the embodiment of the present invention.

FIG. 4 is a cross-sectional view of the thin film transistor substrate taken along the line A-A of FIG. 3.

FIG. 5 is a plan view explaining a line change region of the thin film transistor substrate according to the embodiment of the present invention.

FIG. 6 is an enlarged view of a portion E shown in FIG. 5.

FIG. 7 is a cross-sectional view of the thin film transistor substrate taken along the line B-B of FIG. 6.

FIG. 8 is a diagram showing results of Auger electron spectroscopy (AES) analysis for explaining the principle of connection between a pixel electrode and a drain electrode in the thin film transistor substrate according to the embodiment of the present invention.

FIG. 9 is a cross-sectional view of a structure used to calculate the results shown in FIG. 8.

FIG. 10 illustrates cross sections of process steps of forming the thin film transistor substrate according to the embodiment of the present invention.

FIG. 11 illustrates cross sections of process steps of forming the thin film transistor substrate according to the embodiment of the present invention.

FIG. 12 illustrates cross sections of process steps of forming a connection region in which a scanning line and a signal line are connected together in the thin film transistor substrate according to the embodiment of the present invention.

FIG. 13 illustrates cross sections of process steps of forming the connection region in which the scanning line and the signal line are connected together in the thin film transistor substrate according to the embodiment of the present invention.

FIG. 14 illustrates cross sections of process steps of forming a counter substrate according to the embodiment of the present invention.

FIG. 15 illustrates cross sections of process steps of forming a thin film transistor substrate according to a variation of the present invention.

FIG. 16 illustrates cross sections of process steps of forming the thin film transistor substrate according to the variation of the present invention.

FIG. 17 illustrates cross sections of process steps of forming a connection region in which a scanning line and a signal line are connected together in the thin film transistor substrate according to the variation of the present invention.

### DESCRIPTION OF EMBODIMENTS

An embodiment of the present invention will be described hereinafter with reference to the drawings. The present invention is not limited to the following embodiment.

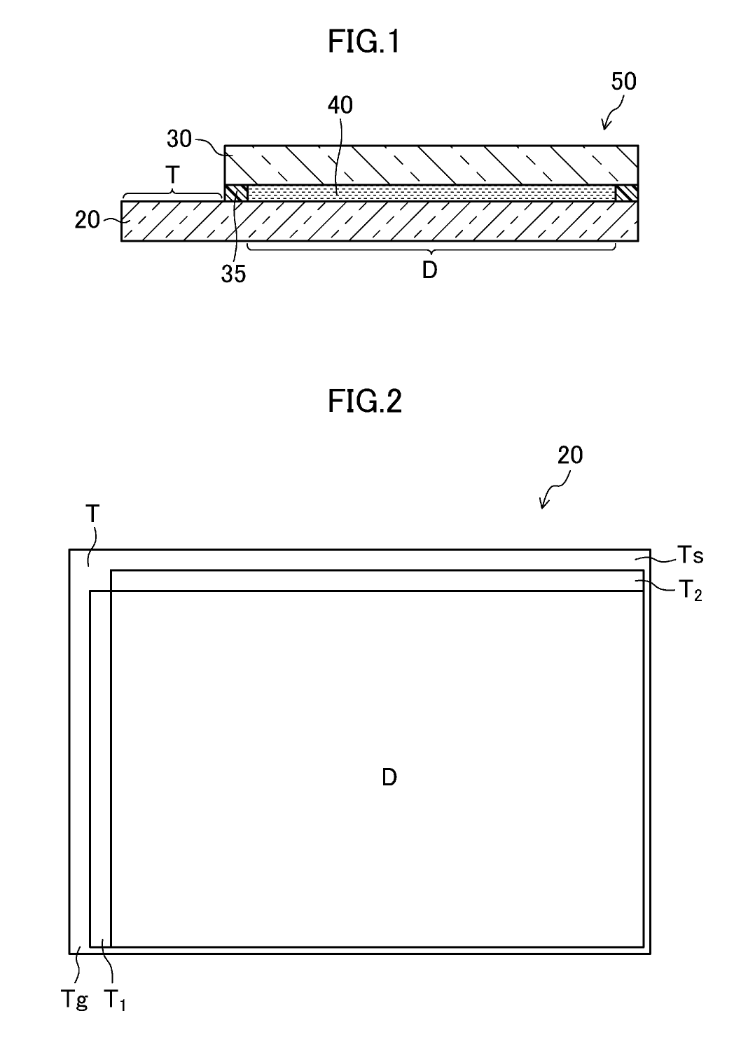

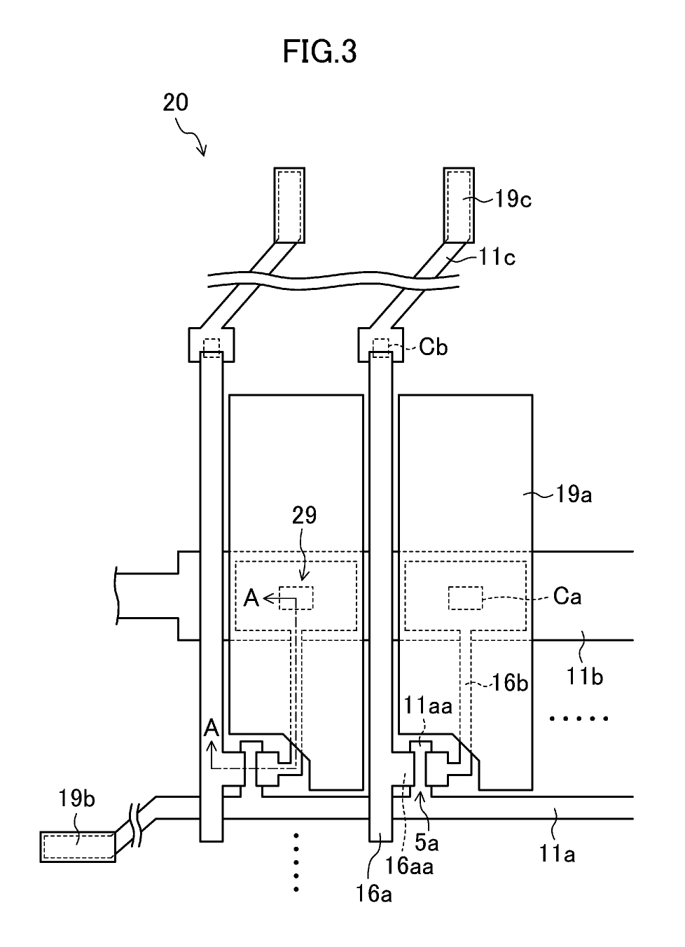

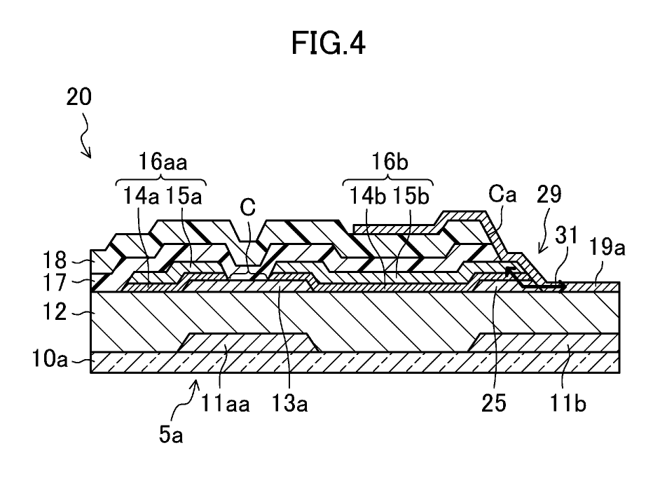

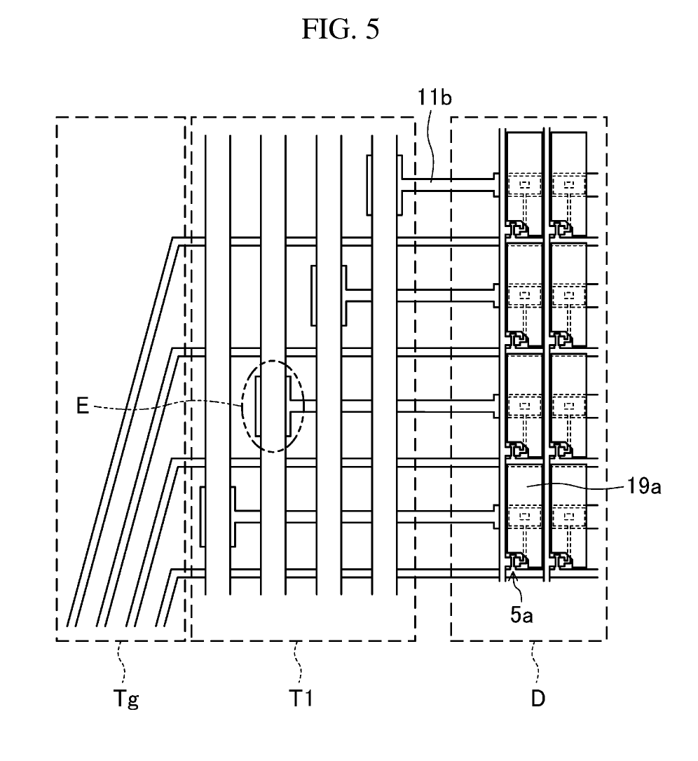

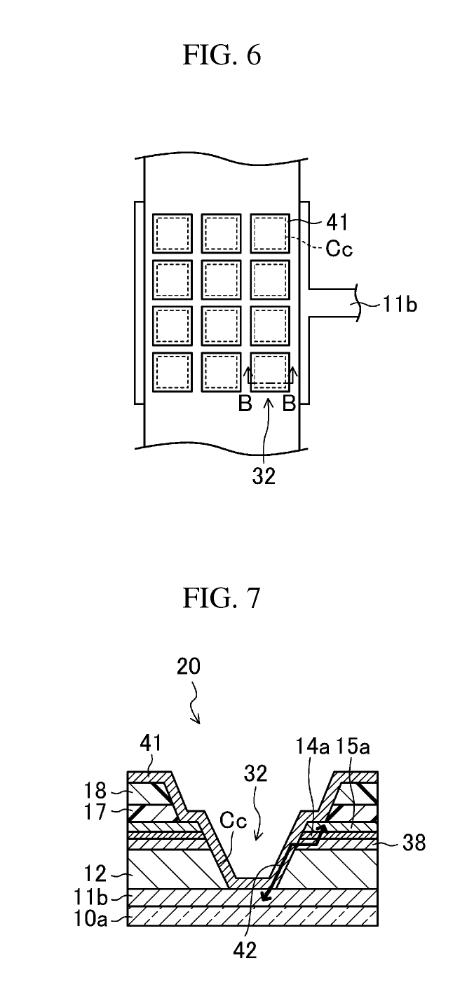

FIG. 1 is a cross-sectional view of a liquid crystal display device having a thin film transistor substrate according to the embodiment of the present invention, and FIG. 2 is a plan view of the thin film transistor substrate according to the embodiment of the present invention. FIG. 3 is an enlarged plan view illustrating a pixel area and a terminal area of the thin film transistor substrate according to the embodiment of the present invention, and FIG. 4 is a cross-sectional view of the thin film transistor substrate taken along the line A-A of FIG. 3. FIG. 5 is a plan view explaining a line change region of the thin film transistor substrate according to the embodiment of the present invention, and FIG. 6 is an enlarged view of a portion E shown in FIG. 5. FIG. 7 is a cross-sectional view of the thin film transistor substrate taken along the line B-B of FIG. 6.

As illustrated in FIG. 1, a liquid crystal display device 50 includes: a thin film transistor substrate 20 which is a display device substrate; a counter substrate 30 which is another display device substrate to be opposed to the thin film transistor substrate 20; a liquid crystal layer 40 which is a display medium layer provided between the thin film transistor substrate 20 and the counter substrate 30; and a frame-shaped sealing material 35 provided to bond the thin film transistor substrate 20 and the counter substrate 30 together, and enclose the liquid crystal layer 40 between the thin film transistor substrate 20 and the counter substrate 30.

As illustrated in FIG. 1, in the liquid crystal display device 50, a display region D which is used to display an image is defined inside the sealing material 35, and a terminal region T is defined on a portion of the thin film transistor substrate 20 protruding from the counter substrate 30.

As illustrated in FIGS. 3 and 4, the thin film transistor substrate 20 includes an insulating substrate 10a and also includes, in the display region D, a plurality of gate lines (scanning lines) 11a extending in parallel with each other on the insulating substrate 10a, a plurality of auxiliary capacitor lines 11b each provided between the respective gate lines 11a and extending in parallel with each other, and a plurality of source lines (signal lines) 16a orthogonal to the scanning lines 11a and extending in parallel with each other. The thin film transistor substrate 20 also includes: a plurality of TFTs 5a provided at respective intersections of the gate lines 11a and the source lines 16a, i.e., for respective pixels; an interlayer insulating film 17 covering the TFTs 5a; and a planarization film 18 covering the interlayer insulating film 17. The thin film transistor substrate 20 also includes a plurality of pixel electrodes 19a arranged in a matrix on the planarization film 18 and connected to the TFTs 5; and an alignment film (not shown) covering the pixel electrodes 19a.

The gate lines 11a extend to a gate terminal region Tg of the terminal region T illustrated in FIG. 2, and each of the gate lines 11a is connected to an associated one of gate terminals 19b in this gate terminal region Tg, as illustrated in FIG. 3.

In a source terminal region Ts of the terminal region T illustrated in FIG. 2, relay lines 11c illustrated in FIG. 3 are provided, and in the source terminal region Ts, the relay lines 11c are connected to source terminals 19c.

As illustrated in FIG. 3, the source lines 16a are connected to the relay lines 11c through contact holes Cb formed in a gate insulating layer 12.

Each of the TFTs 5a has a bottom-gate structure and, as illustrated in FIGS. 3 and 4, includes: a gate electrode 11aa provided on the insulating substrate 10a; a gate insulating layer 12 provided over the gate electrode 11aa; and an oxide semiconductor layer 13a located on the gate insulating layer 12 and having an island-shape channel region C overlapping with the gate electrode 11aa. Each of the TFTs 5a also has a source electrode 16aa and a drain electrode 16b provided on the oxide semiconductor layer 13a, overlapping with the gate electrode 11aa, and facing each other with the channel region C sandwiched therebetween.

In this configuration, the interlayer insulating film 17 covering the source electrode 16aa and the drain electrode 16b (i.e., the TFTs 5a) is provided on the channel region C of the oxide semiconductor layer 13a.

As illustrated in FIG. 3, the gate electrode 11aa projects from a side of an associated one of the gate lines 11a. As also illustrated in FIG. 3, the source electrode 16aa projects from a side of an associated one of the source lines 16a, and as illustrated in FIG. 4, is constituted by a multilayer film of a first conductive layer 14a and a second conductive layer 15a. As also illustrated in FIG. 4, the drain electrode 16b is constituted by a multilayer film of a first conductive layer 14b and a second conductive layer 15b.

The first conductive layers 14a and 14b are made of, e.g., titanium and the second conductive layers 15a and 15b are made of, e.g., aluminum. The drain electrode 16b overlaps the auxiliary capacitor line 11b through the gate insulating layer 12, thereby forming an auxiliary capacitor.

The oxide semiconductor layer 13a is made of an oxide semiconductor of, e.g., indium gallium zinc oxide (IGZO).

In this embodiment, as illustrated in FIG. 2, a line change region T₁ is provided between the display region D and the gate terminal region Tg of the terminal region T, and a line change region T₂ is provided between the display region D and the source terminal region Ts of the terminal region T.

In order to electrically connect the plurality of auxiliary capacitor lines 11b to each other, each of the auxiliary capacitor lines 11b being provided between the respective gate lines 11a and extending in parallel with each other, it is necessary to connect the auxiliary capacitor lines 11b together through other lines (i.e., the source lines 16a) except the gate lines 11a provided in the same layer as the auxiliary capacitor lines 11b, and therefore, the line change region T₁ is a region for ensuring an electric connection between the gate line 11a and the signal lines 16 to connect the plurality of the auxiliary capacitor lines 11b together through the source lines 16a.

The line change region T₂ is a region which changes the line between the source lines 16a and the gate lines 11a, and the source terminals 19c and the source lines 16a are made of the same metal as the gate lines 11a, thereby reducing improper mounting caused by problems such as corrosion since there is no barrier metal in the upper layer like a case where the source lines 16a are made of a multilayer film of, such as aluminum/titanium, copper/titanium. Moreover, the formation of the line change region T₂ can improve reworkability to correct defects which occur when forming the source terminals 19c and the source lines 16a since the source terminals 19c and the source lines 16a are simultaneously formed in the formation of the gate lines 11a.

As illustrated in FIG. 6, in the line change region T₁, a plurality of connection regions 32 in which the auxiliary capacitor line 11b that is a line formed by the gate line layer is connected to the line formed by the source line layer (line constituted by the first conductive layer 14a constituting the source line 16a and the second conductive layer 15a) together are provided, and as illustrated in FIG. 7, each of the connection regions 32 includes: the auxiliary capacitor line 11b formed by the gate line layer and provided on the insulating substrate 10a; the gate insulating layer 12 covering the auxiliary capacitor line 11b the line constituted by the first conductive layer 14a and the second conductive layer 15a and provided on the gate insulating layer 12; the interlayer insulating film 17 provided on the line; and the planarization film 18 covering the interlayer insulating film 17.

As well as the source electrode 16aa described above, the source line 16a is made of a multilayer film of the first conductive layer 14a and the second conductive layer 15a.

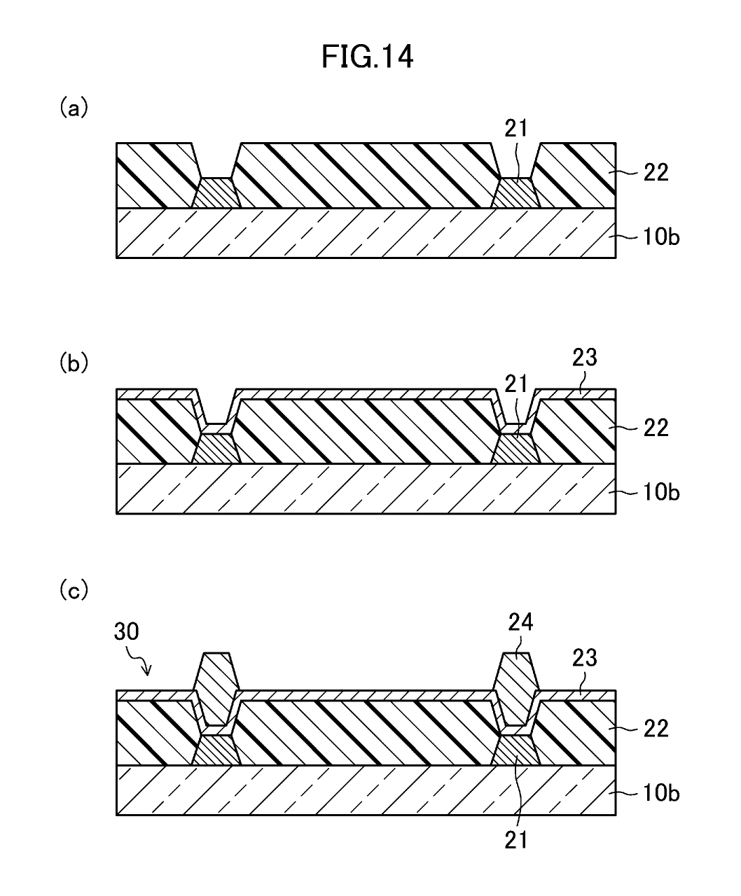

As illustrated FIG. 14(c), which will be referred to later, the counter substrate 30 includes: an insulating substrate 10b; a color filter layer located on the insulating substrate 10b and including a lattice-shaped black matrix 21 and colored films 22, such as a red film, a green film, and a blue film, provided in the respective lattices of the black matrix 21. The counter substrate 30 also includes: a common electrode 23 covering the color filter layer; photospacers 24 located on the common electrode 23; and an alignment film (not shown) covering the common electrode 23.

The liquid crystal layer 40 is made of, for example, a nematic liquid crystal material having electrooptic properties.

In each of the pixels in the liquid crystal display device 50 having the above-described configuration, when a gate signal is transmitted from a gate driver (not shown) to the gate electrode 11aa through the gate line 11a to turn on the TFT 5a, a source signal is sent from a source driver (not shown) to the source electrode 16aa through the signal line 16a, thereby writing a predetermined amount of charge in the pixel electrode 19a through the oxide semiconductor layer 13a and the drain electrode 16b.

In this process, a potential difference occurs between the pixel electrode 19a of the active matrix substrate 20 and the common electrode 23 of the counter substrate 30, resulting in that a predetermined voltage is applied to the liquid crystal layer 40, i.e., a liquid crystal capacitor of each pixel and an auxiliary capacitor connected to the liquid crystal capacitor in parallel.

In each of the pixels in the liquid crystal display device 50, the alignment state of the liquid crystal layer 40 is changed depending on the level of the voltage applied to the liquid crystal layer 40. In this manner, an image is displayed with adjustment of the light transmittance of the liquid crystal layer 40.

As illustrated in FIGS. 3 and 4, as a feature of this embodiment, the connection region 29 in which the pixel electrode 19a and the drain electrode 16b are connected together is provided with a connection layer 25 which electrically connects the pixel electrode 19a and the drain electrode 16b together, and the connection layer 25 is made of an oxide semiconductor.

As illustrated in FIG. 4, in the connection region 29, the connection layer 25 is provided on the gate insulating layer 12, and the drain electrode 16b is provided on the connection layer 25. As illustrated in FIGS. 3 and 4, in the connection region 29, a contact hole Ca is formed in the drain electrode 16b, the interlayer insulating film 17, the planarization film 18, and the connection layer 25, and the pixel electrode 19a is formed on the surface of the contact hole Ca.

The pixel electrode 19a and the drain electrode 16b are electrically connected together through the connection layer 25 made of the oxide semiconductor by a connection path 31 illustrated by an arrow in FIG. 4.

As well as the oxide semiconductor layer 13a described above, as the oxide semiconductor which constitutes the connection layer 25, an oxide semiconductor made of, e.g., indium gallium zinc oxide (IGZO) can be used.

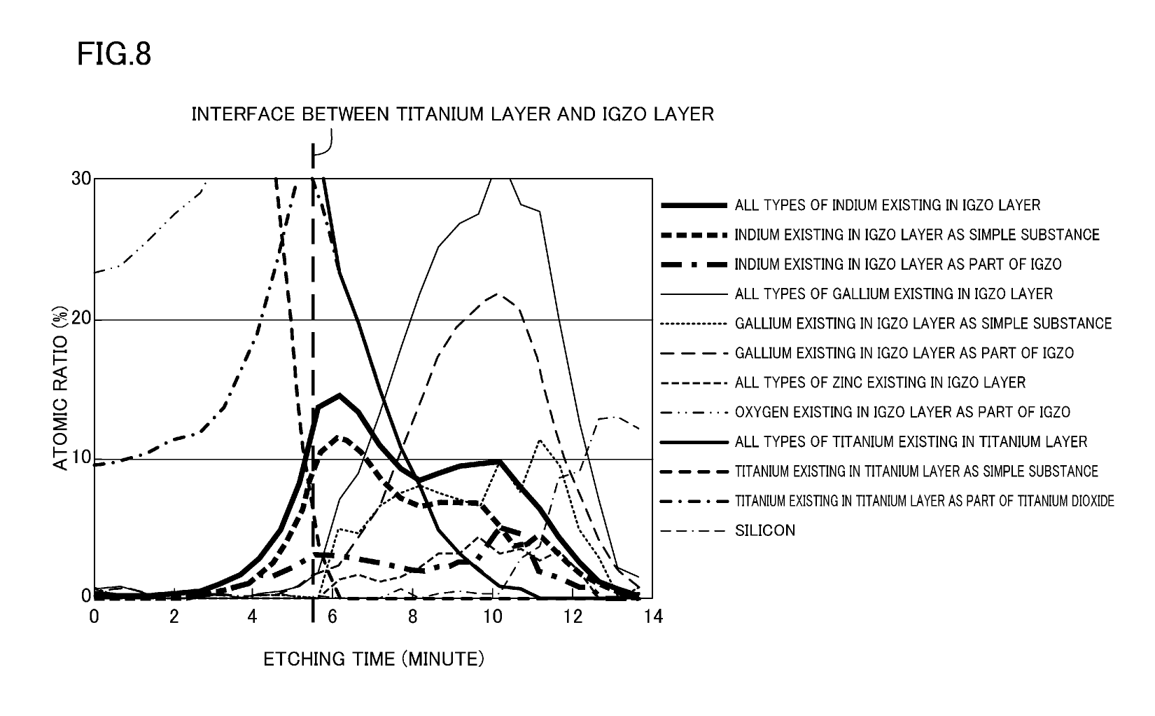

Next, the principle of connection between the pixel electrode 19a and the drain electrode 16b through the connection layer 25 made of the oxide semiconductor will be described. FIG. 8 is a diagram showing results of Auger electron spectroscopy (AES) analysis for explaining the principle of connection between the pixel electrode and the drain electrode in the thin film transistor substrate according to the embodiment of the present invention.

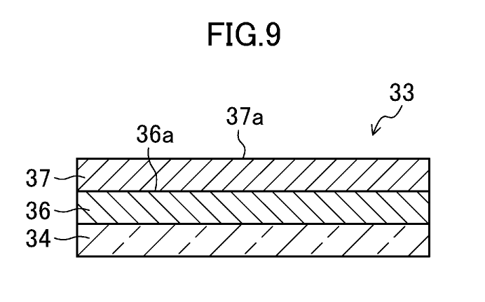

The results shown in FIG. 8 are obtained by etching a structure 33, illustrated in FIG. 9, including a glass substrate 34, an IGZO layer 36, and a titanium layer 37, from a side closer to a surface of 37a of the titanium layer 37 for a predetermined period of time by using Ar and a sputtering gun, and performing Auger electron spectroscopy (AES) analysis in each etching time to calculate atomic ratios.

As can be seen from FIG. 8, at an interface between the titanium layer 37 and the IGZO layer 36 (i.e., a surface 36a of the IGZO layer contacting the titanium layer 37 illustrated in FIG. 9), it is found that an atomic ratio of indium existing in the IGZO layer 36 as a simple substance is larger than that of indium existing in the IGZO layer 36 as part of IGZO. Therefore, it is found that, of all types of indium existing in the IGZO layer 36, the indium existing as the simple substance is a main component, and at the interface between the titanium layer 37 and the IGZO layer 36, indium included in the IGZO layer 36 is reduced by titanium.

Similarly, as can be seen from FIG. 8, at the interface between the titanium layer 37 and the IGZO layer 36; it is found that an atomic ratio of titanium existing in the titanium layer 37 as part of a titanium dioxide is larger than that of titanium existing in the titanium layer 37 as a simple substance. Therefore, it is found that, of all types of titanium existing in the titanium layer 37, the titanium existing as the part of the titanium dioxide is a main component, and at the interface between the titanium layer 37 and the IGZO layer 36, titanium is oxidized by indium included in the IGZO.

In other words, in this embodiment, the oxide semiconductor (IGZO) which constitutes the connection layer 25 is reduced by the titanium which constitutes the first conductive layer 14b of the drain electrode 16b contacting the connection layer 25, and therefore, it becomes possible to cause a decrease in resistance of the connection layer 25 made of the oxide semiconductor.

As described above, since in this embodiment, the pixel electrode 19a and the drain electrode 16b can be connected together through the connection layer 25 whose resistance is decreased, unlike the above-described conventional techniques, it is unnecessary to perform an etching process for connecting the pixel electrode 19a and the drain electrode 16b together. Therefore, it becomes possible to prevent a poor connection between the pixel electrode 19a and the drain electrode 16b to prevent deterioration of display quality without causing an increase in the number of fabrication process steps.

If the second conductive layer 15b is made of copper, when the interlayer insulating film 17 is formed on the second conductive layer 15b, an oxide film (copper oxide) is formed on the surface of the second conductive layer 15b. However, in this embodiment, the pixel electrode 19a and the drain electrode 16b can be connected together through the connection layer 25 whose resistance is decreased, and therefore, the step of removing the oxide film is not needed.

In this embodiment, as illustrated in FIGS. 6 and 7, as a feature of this embodiment, the connection region 32 in which the auxiliary capacitor line 11b formed by the gate line layer and the line formed by the source line layer (line constituted by the first conductive layer 14a and the second conductive layer 15a constituting the source line 16a) are connected together is provided with a connection layer 38 which electrically connects the auxiliary capacitor line 11b and the line formed by the source line layer together, and the connection layer 38 is made of an oxide semiconductor.

As illustrated in FIG. 7, in the connection region 32, the connection layer 38 is formed on the gate insulating layer 12, and the line constituted by the first conductive layer 14a and the second conductive layer 15a is formed on the connection layer 38. As illustrated in FIGS. 6 and 7, in the connection region 32, a contact hole Cc is formed in the gate insulating layer 12, the line constituted by the first conductive layer 14a and the second conductive layer 15a, the interlayer insulating film 17, the planarization film 18, and the connection layer 38, and a transparent conductive film 41 made of, e.g., an ITO film of indium tin oxide is formed on the surface of the contact hole Cc.

The auxiliary capacitor line 11b and the line constituted by the first conductive layer 14a and the second conductive layer 15a are electrically connected together through the connection layer 38 made of the oxide semiconductor and the transparent conductive film 41 by a connection path 42 illustrated by an arrow in FIG. 7.

As well as the oxide semiconductor layer 13a and the connection layer 25 described above, as the oxide semiconductor which constitutes the connection layer 38, an oxide semiconductor made of, e.g., indium gallium zinc oxide (IGZO) can be used.

As well as the connection region 29 provided with the connection layer 25 described above, in the connection region 32, the oxide semiconductor (IGZO) which constitutes the connection layer 38 is reduced by the titanium which constitutes the first conductive layer 14a of the source line 16a contacting the connection layer 38, and therefore, it becomes possible to cause a decrease in resistance of the connection layer 38 made of the oxide semiconductor.

Therefore, since in this embodiment, the auxiliary capacitor line 11b and the line constituted by the first conductive layer 14a and the second conductive layer 15a can be connected together through the connection layer 38 whose resistance is decreased, and as well as the connection region 29, it is unnecessary to perform an etching process for connecting the auxiliary capacitor line 11b and the line constituted by the first conductive layer 14a and the second conductive layer 15a together. Therefore, it becomes possible to prevent a poor connection between the auxiliary capacitor line 11b and the line constituted by the first conductive layer 14a and the second conductive layer 15a to prevent deterioration of display quality without causing an increase in the number of fabrication process steps.

In this embodiment, the drain electrode 16b is made of a multilayer film of the first conductive layer 14b and the second conductive layer 15b, and the first conductive layer 14b of the drain electrode 16b contacting the connection layer 25 is made of titanium. Therefore, even if the drain electrode 16b is made of the multilayer film of the first conductive layer 14b and the second conductive layer 15b, and a poor connection occurs between the pixel electrode 19a and the second conductive layer 15b, the pixel electrode 19a and the second conductive layer 15b of the drain electrode 16b can be connected together through the connection layer 25 whose resistance is decreased.

Similarly, the line formed by the source line layer is made of a multilayer film of the first conductive layer 14a and the second conductive layer 15a, and the first conductive layer 14a contacting the connection layer 38 is made of titanium. Therefore, even if the line formed by the source line layer is made of the multilayer film of the first conductive layer 14a and the second conductive layer 15a, and a poor connection occurs between the transparent conductive film 41 and the second conductive layer 15a, the auxiliary capacitor line 11b and the second conductive layer 15a can be connected together through the connection layer 38 whose resistance is decreased.

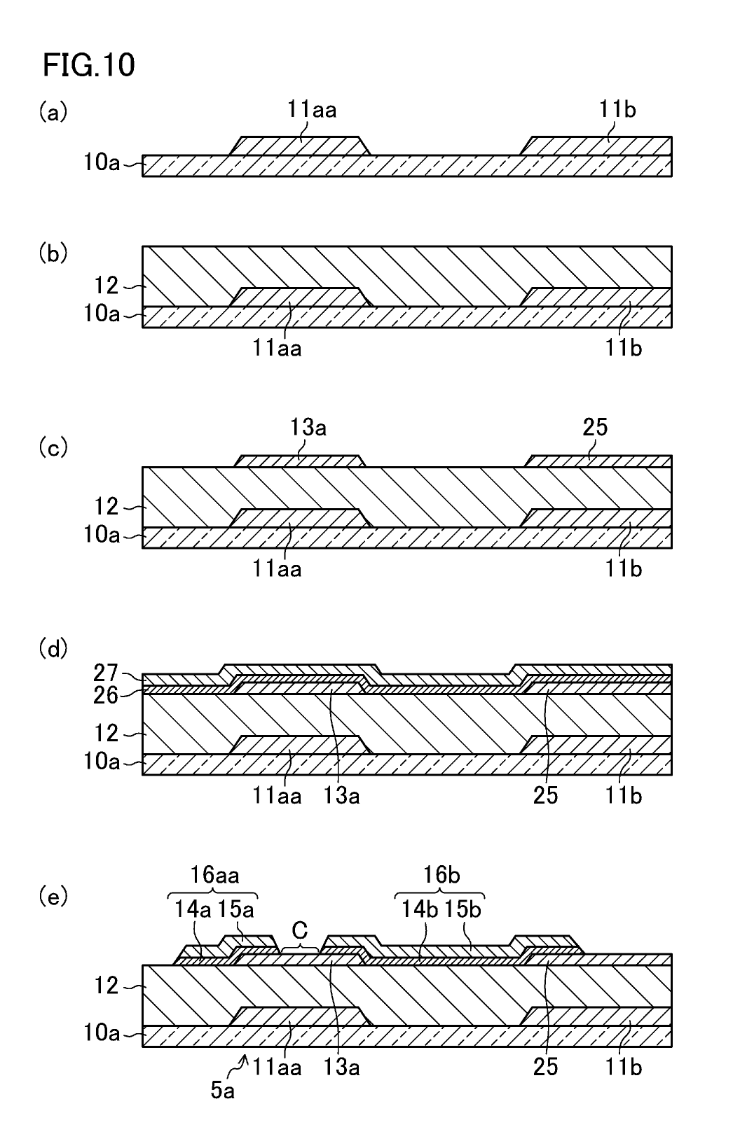

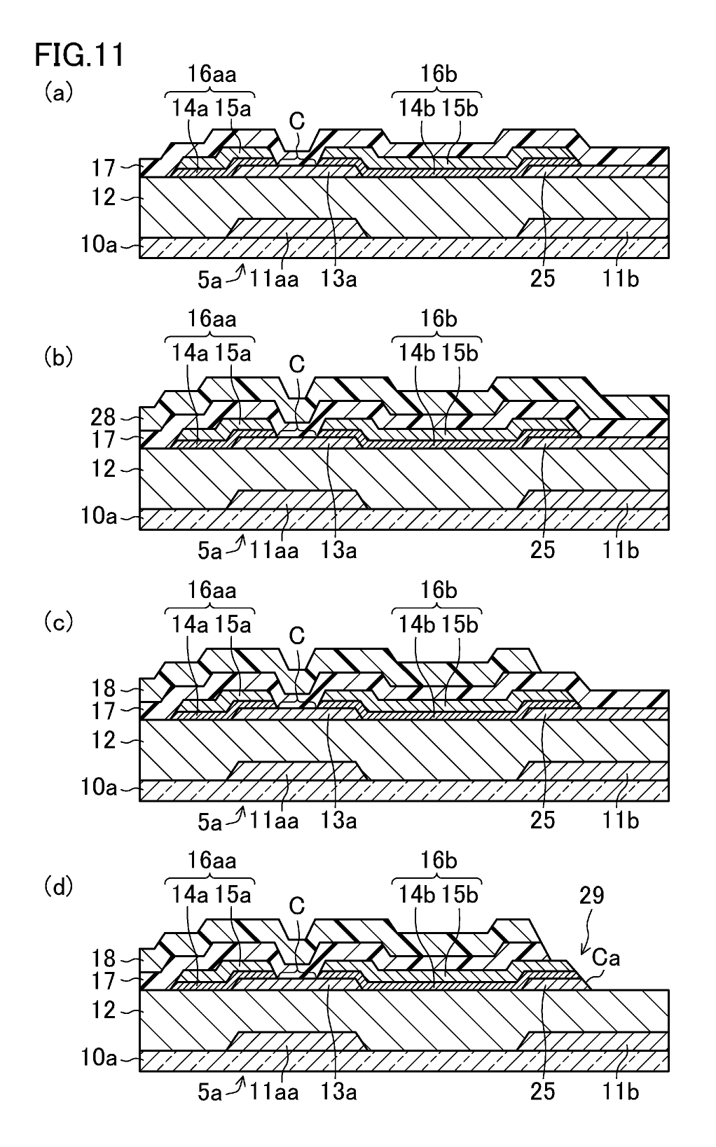

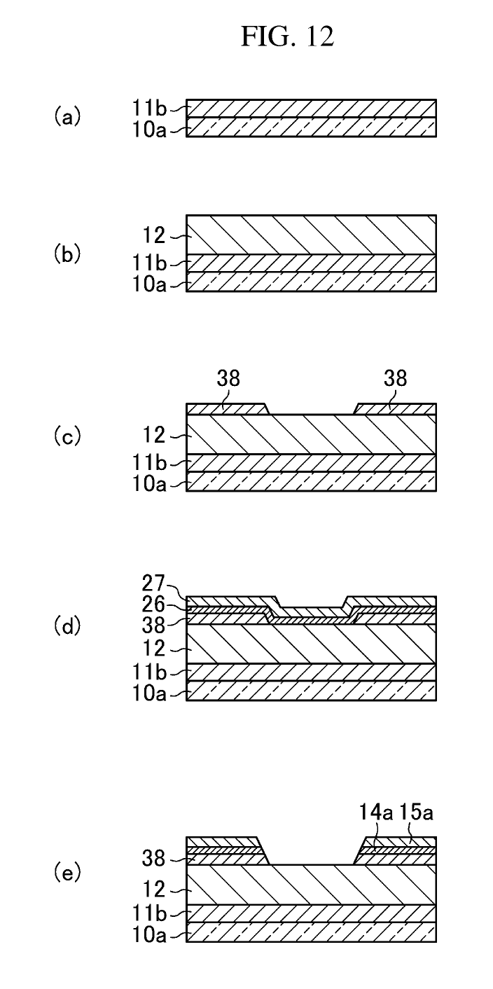

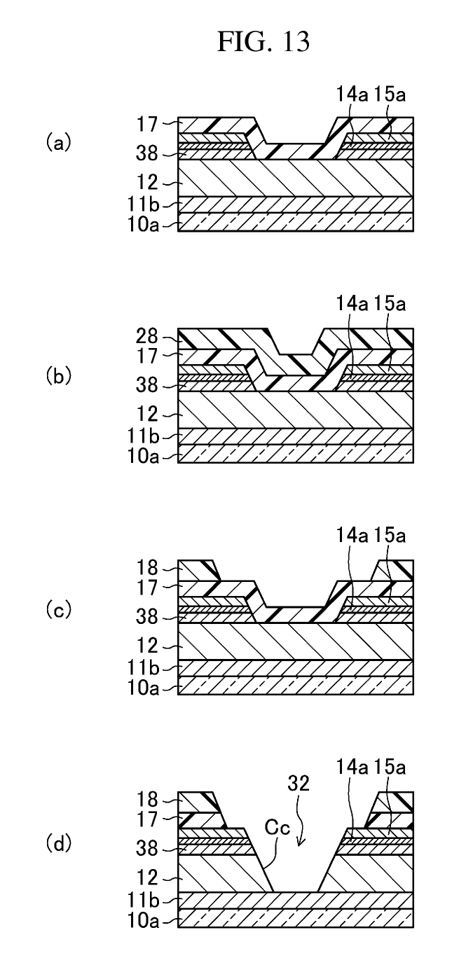

Next, an example method for fabricating the liquid crystal display device 50 according to this embodiment will be described with reference to FIGS. 10-14. FIGS. 10 and 11 illustrate cross sections of process steps of forming the thin film transistor substrate according to the embodiment of the present invention, and FIGS. 12 and 13 illustrate cross sections of process steps of forming the connection region in which the scanning line and the signal line are connected together in the thin film transistor substrate according to the embodiment of the present invention. FIG. 14 illustrates cross sections of process steps of forming the counter substrate according to the embodiment of the present invention. The fabrication method in the embodiment includes a thin film transistor substrate formation step, a counter substrate formation step, and a liquid crystal injection step.

Process steps of forming the thin film transistor substrate will now be described.

<Gate Electrode and Gate Line Formation Step>

First, for example, a molybdenum film (with a thickness of about 150 nm) is deposited by sputtering over the entire surface of an insulating substrate 10a such as a glass substrate, a silicon substrate, a heat-resistant plastic substrate, etc. Thereafter, patterning of a resist by photolithography with a first photomask, wet etching of the molybdenum film, removal of the resist, and cleaning are performed, thereby forming the gate lines 11a, the gate electrodes 11aa, the auxiliary capacitor lines 11b, and the relay lines 11c on the insulating substrate 10a, as illustrated in FIGS. 3, 10(a) and 12(a).

In this embodiment, the molybdenum film having a single-layer structure is illustrated as a metal film which constitutes the gate electrodes 11aa. Alternatively, the gate electrodes 11aa may be made of a metal film, such as an aluminum film, a tungsten film, a tantalum film, a chromium film, a titanium film, a copper film, etc., or an alloy or metal nitride film thereof which have a thickness of 50 nm-300 nm.

The plastic substrate may be made of, for example, polyethylene terephthalate resin, polyethylene naphthalate resin, polyethersulfone resin, acrylic resin, or polyimide resin.

<Gate Insulating Layer Formation Step>

Next, for example, a silicon nitride film (with a thickness of about 200 nm-500 nm) is deposited by CVD over the entire substrate on which the gate lines 11a, the gate electrodes 11aa, and the auxiliary capacitor lines 11b are formed, thereby forming the gate insulating layer 12 covering the gate lines 11a, the gate electrodes 11aa, and the auxiliary capacitor lines 11b, as illustrated in FIGS. 10(b) and 12(b).

The gate insulating layer 12 may be made of a multilayer film of two layers. In this case, in addition to the silicon nitride film (SiNₓ), a silicon oxide film (SiOₓ), a silicon oxynitride film (SiOₓN_{y}, x>y), or a silicon nitride oxide film (SiNₓO_{y}, x>y), for example, may be used.

To prevent diffusion of, for example, an impurity from the insulating substrate 10a, a silicon nitride film or a silicon nitride oxide film is preferably used as a lower gate insulating layer, whereas a silicon oxide film or a silicon oxynitride film is preferably used as an upper gate insulating layer. For example, a silicon nitride film with a thickness of 100 nm-200 nm may be formed as a lower gate insulating layer using SiH₄ and NH₃ as a reactant gas, and a silicon oxide film with a thickness of 50 nm-100 nm may be formed using N₂O and SiH₄ as a reactant gas.

To deposit a dense gate insulating layer 12 with a small gate leakage current at a low temperature, a rare gas such as an argon gas is preferably contained in the reactant gas to be mixed in the insulating layer.

<Semiconductor Layer and Connection Layer Formation Step>

Thereafter, for example, an oxide semiconductor film (with a thickness of about 30 nm-100 nm) of indium gallium zinc oxide (IGZO) is deposited by sputtering. Then, patterning of a resist by photolithography with a second photomask, wet etching of the oxide semiconductor film, removal of the resist, and cleaning are performed thereby forming the oxide semiconductor layers 13a, and the connection layers 25 and 38 on the gate insulating layer 12, as illustrated in FIGS. 10(c) and 12(c).

<Source Line and Drain Electrode Formation Step>

Next, as illustrated in FIGS. 10(d) and 12(d), for example, a titanium film 26 (with a thickness of about 30 nm-150 nm) and an aluminum film 27 (with a thickness of about 50 nm-400 nm), etc., are sequentially deposited by sputtering over the entire substrate on which the oxide semiconductor layers 13a and the connection layer 25 and 38 are formed.

Thereafter, patterning of a resist by photolithography with a third photomask, wet etching of the aluminum film are performed, and dry etching (plasma etching) of the titanium film, removal of the resist, and cleaning are performed. As illustrated in FIG. 10(e), the source electrode 16aa each of which are made of a multilayer film of the first conductive layer 14a and the second conductive layer 15a are formed on the oxide semiconductor layers 13a, and the drain electrodes 16b each of which is made of a multilayer film of the first conductive layer 14b and the second conductive layer 15b are formed on the connection layers 25 to expose the channel regions C of the oxide semiconductor layers 13a. As illustrated in FIG. 12(e), the lines formed by the source line layers each of which is made of a multilayer film of the first conductive layer 14a and the second conductive layer 15a are formed on the connection layers 38.

In other words, in this step, the drain electrode 16b is formed by dry etching on the connection layer 25 which has been formed in the connection layer formation step, whereby the connection layer 25 and the first conductive layer 14b of the drain electrode 16b are in contact with each other.

Similarly, the lines formed by the source line layers are formed by dry etching on the connection layers 38 which have been formed in the connection layer formation step, whereby the connection layer 38 and the first conductive layer 14a that is the line formed by the source line layer are in contact with each other.

In the etching process, either the dry etching described above or the wet etching described above may be used, and if a substrate having a large area is processed, the dry etching is preferably used. A fluorine-based gas, such as CF₄, NF₃, SF₆, CHF₃, etc., a chlorine-based gas, such as Cl₂, BCl₃, SiCl₄, CCl₄, etc., an oxygen-based gas, etc., can be used as an etching gas, and an inert gas, such as helium and argon, etc., may be added.

<Interlayer Insulating Film Formation Step>

Thereafter, for example, a silicon nitride film, a silicon oxide film, or a silicon nitride oxide film, etc., is deposited by plasma CVD over the entire substrate on which the source and drain electrodes 16aa and 16b (i.e., the TFTs 5a), and the lines formed by the source line layers are formed, thereby forming an interlayer insulating film 17 having a thickness of about 400 nm, and covering the TFTs 5a (i.e., the oxide semiconductor layers 13a, the source electrodes 16aa, the drain electrodes 16b, and the connection layers 25), the lines formed by the source line layers, and the connection layers 38, as illustrated in FIGS. 11(a) and 13(a). The structure of the interlayer insulating film 17 is not limited to have a single-layer structure, and may have a two-layer or a three-layer structure.

<Planarization Film Formation Step>

Next, the entire substrate including the interlayer insulating film 17 is coated with a photosensitive organic insulating film 28 made of, for example, a photosensitive acrylic resin, and having a thickness of about 1.0 μm-3.0 μm by spin coating or slit coating, as illustrated in FIGS. 11(b) and 13(b).

Next, patterning of a resist by photolithography with a fourth photomask, exposure and development of the organic insulating film 28, removal of the resist, and cleaning are performed, thereby forming the planarization film 18 on the surface of the interlayer insulating film 17, as illustrated in FIGS. 11(c) and 13(c).

<Contact Hole Formation Step>

Next, dry etching is performed by using a predetermined etching gas (for example, a CF₄ gas and an O₂ gas) with the planarization film 18, the source electrodes 16aa and the drain electrodes 16b as masks to remove part of the interlayer insulating film 17 and part of the connection layers 25, thereby forming the contact holes Ca in the connection layers 25 and the drain electrodes 16b to form the connection layers 29 each in which the contact hole Ca is formed, as illustrated in FIG. 11(d).

Dry etching is performed by using a predetermined etching gas (for example, a CF₄ gas and an O₂ gas) with the planarization film 18, the lines formed by the source line layers, and the connection layers 38 as masks to remove part of the interlayer insulating film 17 and part of the gate insulating layer 12, thereby forming the contact holes Cc in the gate insulating layer 12, the connection layers 38, and the lines formed by the source line layers to form the connection layers 32 each in which the contact hole Cc is formed, as illustrated in FIG. 13(d).

The contact holes Cb described above are formed at the same time of forming the contact holes Ca and Cc by etching of the gate insulating layer 12.

When the contact holes Ca and Cc are formed, the etching selectivity of the connection layer 25 at the side of the contact hole Ca, and the etching selectivity of the gate insulating layer 12 at the side of the contact hole Cc are adjust, thereby stopping the etching at the connection layer 25 at the side of the contact hole Ca to make it possible to prevent etching of the gate insulating layer 12.

<Pixel Electrode and Transparent Conductive Film Formation Step>

Finally, for example, an ITO film (with a thickness of about 50 nm-200 nm) of indium tin oxide is deposited by sputtering over the entire substrate on which the interlayer insulating film 17 and the planarization film 18 are formed. Then, patterning of a resist by photolithography with a fifth photomask, wet etching of the ITO film, removal of the resist, and cleaning are performed, thereby forming the pixel electrodes 19a on the surfaces of the contact holes Ca, as illustrated in FIG. 4, and the transparent conductive films 41 on the surfaces of the contact holes Cc, as illustrated in FIG. 7.

At this time, as illustrated in FIG. 4, the pixel electrode 19a is formed to contact the connection layer 25, and the pixel electrode 19a and the drain electrode 16b are electrically connected together through the connection layer 25 made of the oxide semiconductor by the connection path 31.

As described above, in this embodiment, the pixel electrode 19a and the drain electrode 16b can be connected together through the connection layer 25 without an etching process for connecting the pixel electrode 19a and the drain electrode 16b together. Therefore, it becomes possible to prevent a poor connection between the pixel electrode 19a and the drain electrode 16b to prevent deterioration of display quality without causing an increase in the number of fabrication process steps.

As illustrated in FIG. 7, the transparent conductive film 41 is formed to contact the auxiliary capacitor line 11b and the connection layer 38, and the auxiliary capacitor line 11b and the line constituted by the first conductive layer 14a and the second conductive layer 15a are electrically connected together through the connection layer 38 made of the oxide semiconductor and the transparent conductive film 41 by the connection path 42.

Therefore, the auxiliary capacitor line 11b and the line constituted by the first conductive layer 14a and the second conductive layer 15a can be connected together through the connection layer 38 without an etching process for connecting the auxiliary capacitor line 11b and the line constituted by the first conductive layer 14a and the second conductive layer 15a together. Therefore, it becomes possible to prevent a poor connection between the auxiliary capacitor line 11b and the line constituted by the first conductive layer 14a and the second conductive layer 15a to prevent deterioration of display quality without causing an increase in the number of fabrication process steps.

In the case of forming a transmissive liquid crystal display device 50, the pixel electrodes 19a may include indium oxide or indium zinc oxide containing tungsten oxide, or include indium oxide or indium tin oxide containing titanium oxide, for example. Instead of indium tin oxide (ITO) described above, indium zinc oxide (IZO) or indium tin oxide (ITSO) containing silicon oxide, for example, may be used.

In the case of forming a reflective liquid crystal display device 50, a conductive film of titanium, tungsten, nickel, gold, platinum, silver, aluminum, magnesium, calcium, lithium, or an alloy containing at least one of these elements may be used as a reflective metal thin film, and this metal thin film may be used for the pixel electrodes 19a.

In the foregoing manner, the thin film transistor substrate 20 illustrated in FIGS. 4 and 7 can be formed.

<Counter Substrate Formation Step>

First, the entire surface of the insulating substrate 10b such as a glass substrate is coated with, for example, a black-colored photosensitive resin by spin coating or slit coating, and then is exposed to light and developed, thereby forming the black matrix 21 with a thickness of about 1.0 nm, as illustrated in FIG. 14(a).

Next, the entire substrate including the black matrix 21 is coated with a red-, green-, or blue-colored photosensitive resin by spin coating or slit coating, and then is exposed to light and developed, thereby forming a colored film 22 of a selected color (e.g., a red film) with a thickness of about 2.0 μm, as illustrated in FIG. 14(a). Similar processes are performed for the other two colors, thereby forming colored films 22 of the other two colors (e.g., a green film and a blue film) each with a thickness of about 2.0 μm.

Then, a transparent conductive film such as an ITO film, for example, is deposited by sputtering over the substrate including the colored films 22, thereby forming a common electrode 23 with a thickness of about 50 nm-200 nm, as illustrated in FIG. 14(b).

Lastly, the entire substrate including the common electrode 23 is coated with a photosensitive resin by spin coating or slit coating, and then is exposed to light and developed, thereby forming photospacers 24 each with a thickness of about 4 μm, as illustrated in FIG. 14(c).

In the foregoing manner, the counter substrate 30 can be formed.

<Liquid Crystal Injection Step>

First, a resin film of polyimide is applied by printing onto the surfaces of the thin film transistor substrate 20 formed by the above-descried thin film transistor substrate formation step and the counter substrate 30 formed by the above-descried counter substrate formation step, and then, is subjected to calcination and rubbing, thereby forming an alignment film.

Next, a sealing material of, for example, an ultraviolet (UV)/thermosetting resin is printed in a frame shape on the surface of the counter substrate 30 on which the alignment film is formed, and then a liquid crystal material is dropped inside the frame of the sealing material.

Thereafter, the counter substrate 30 on which the liquid crystal material has been dropped and the thin film transistor substrate 20 on which the alignment film is formed are bonded together under a reduced pressure to form a bonded assembly. This bonded assembly is then exposed to the air under an atmospheric pressure, thereby pressurizing the front and back surfaces of the bonded assembly.

Subsequently, the sealing material enclosed in the bonded assembly is irradiated with UV light, and then the bonded assembly is heated, thereby curing the sealing material.

Lastly, the bonded assembly enclosing the cured sealing material is diced, for example, and unwanted portions thereof are removed.

In the foregoing manner, the liquid crystal display device 50 of the embodiment is fabricated.

The above embodiment may be modified in the following manner.

In the above embodiment, the connection layer 25 is provided in the contact hole Ca, and the drain electrode 16b and the pixel electrode 19a are electrically connected together through the connection layer 25, and the connection layer 38 is provided in the contact hole Cc, and the auxiliary capacitor line 11b and the line constituted by the first conductive layer 14a and the second conductive layer 15a are electrically connected together through the connection layer 38. However, the present invention is not limited to such configurations, and for example, the contact hole Cb described above can be applied.

For example, as well as the contact hole Cc described above, in the contact hole Cb, a connection layer made of indium gallium zinc oxide (IGZO) may be provided between the gate insulating layer 12 and the source line 16a, and a transparent conductive film contacting the relay line 11c and the connection layer may be provided on the surface of the contact hole Cb, and the relay line 11c and the source line 16a may be electrically connected together through the transparent conductive film and the connection layer.

In the above embodiment, indium gallium zinc oxide (IGZO) is used as an oxide semiconductor constituting the connection layers 25 and 38, and the first conductive layer 14b of the drain electrode 16b contacting the connection layers 25, and the first conductive layer 14a of the line formed by the first conductive layer 14a and the second conductive layer 15a contacting the connection layers 38 are made of titanium. Alternatively, another material except titanium can be used as a metal constituting the first conductive layer 14b of the drain electrode 16b and a metal constituting the first conductive layer 14a of the line formed by the first conductive layer 14a and the second conductive layer 15a as long as an oxide semiconductor constituting the connection layers 25 and 38 are reduced by the metal constituting the first conductive layer 14b of the drain electrode 16b and the metal constituting the first conductive layer 14a of the line formed by the first conductive layer 14a and the second conductive layer 15a to decrease the resistances of the connection layers 25 and 38 made of the oxide semiconductors.

More specifically, for example, if the material is a metal whose standard electrode potential is lower than that of titanium, when the material is in contact with indium gallium zinc oxide, the indium gallium zinc oxide can be reduced as well as the above-described titanium.

Specifically, the standard electrode potential of titanium is −1.63 V, and metals having a standard electrode potential lower than titanium includes, for example, aluminum (−1.676V), barium (−2.92V), beryllium (−1.847V), calcium (−2.84V), cesium (-2.923V), potassium (−2.925V), lithium (−3.045V), magnesium (−2.37V), sodium (Na: −2.714V), rubidium (−2.925), strontium (−2.89V), etc.

In this case, the drain electrode 16b (i.e., the first conductive layer 14b) made of a metal whose standard electrode potential is lower than that of titanium is formed on the connection layer 25, and the source line 16a (i.e., the first conductive layer 14a) made of a metal whose standard electrode potential is lower than that of titanium is formed on the connection layer 38.

In the above embodiment, the thin film transistor substrate 20 is fabricated by using the five photomasks, and alternatively, the thin film transistor substrate may be fabricated by performing the semiconductor layer and connection layer formation step and the source line and drain electrode formation step with one photomask, and using four photomasks in total.

In this case, initially, in the thin film transistor substrate formation step, as well as FIGS. 10(a) and 10(b), and 12(a) and 12(b) described in the above embodiment, the gate electrode and gate line formation step, and the gate insulating layer formation step are performed by using a first photomask.

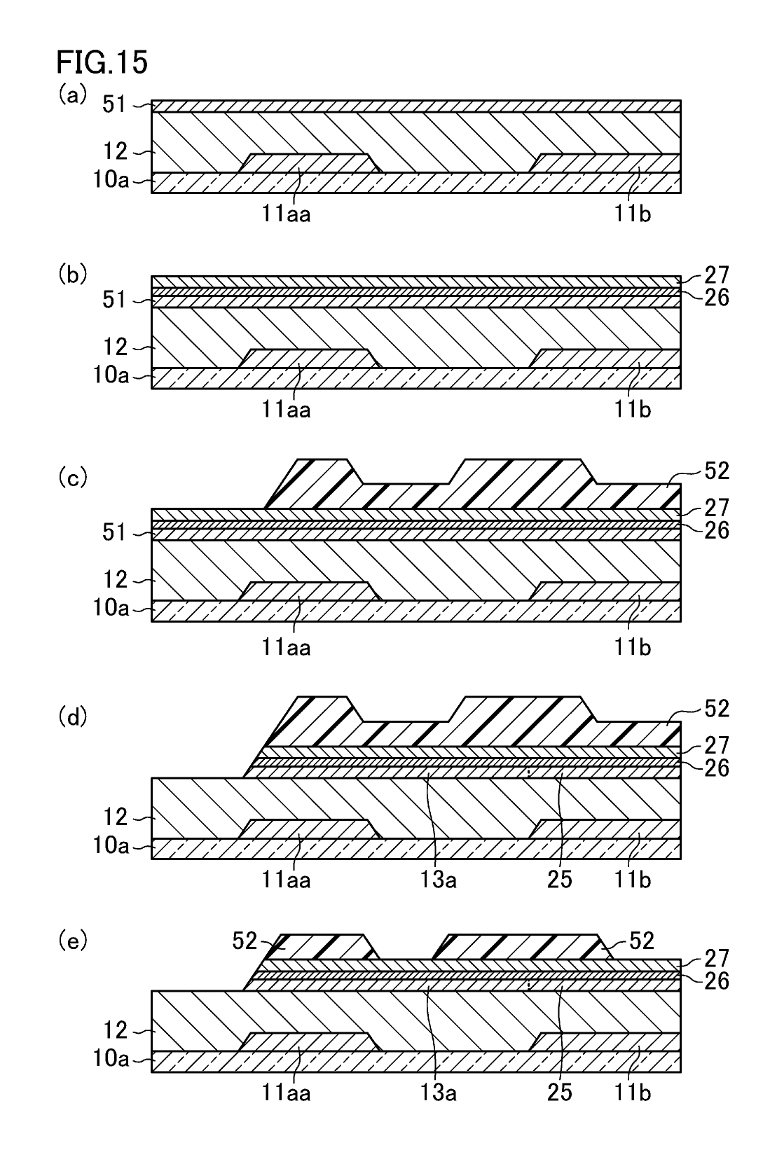

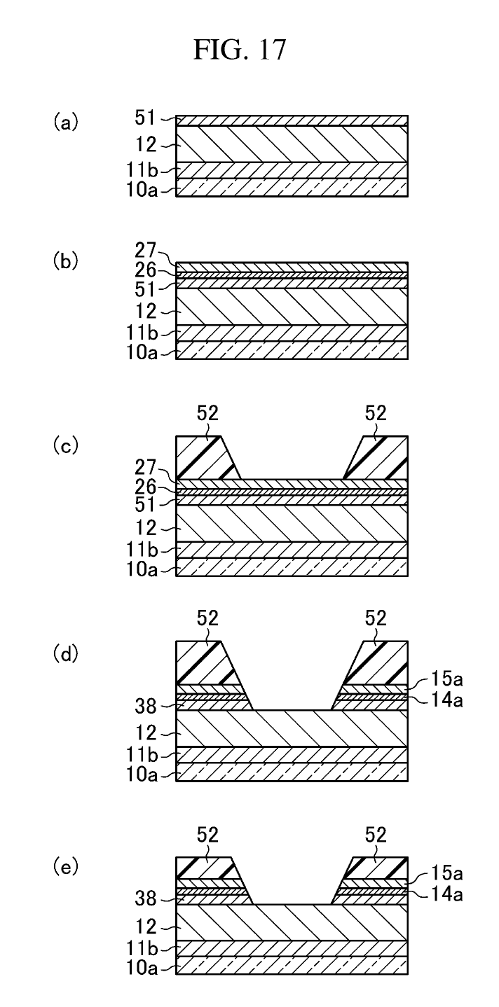

Subsequently, as illustrated in FIGS. 15(a) and 17(a), an oxide semiconductor film (with a thickness of about 30 nm-100 nm) 51 made of, e.g., indium gallium zinc oxide (IGZO) is deposited by sputtering. Next, as illustrated in FIGS. 15(b) and 17(b), a titanium film 26 (with a thickness of about 30 nm-150 nm), an aluminum film 27 (with a thickness of about 50 nm-400 nm), etc., are sequentially formed over the entire substrate on which the oxide semiconductor film 51 is formed by sputtering.

Next, a photoresist is formed over the entire substrate on which the titanium film 26 and the aluminum film 27 are formed, and the photoresist is patterned by half exposure with a second photomask to have a predetermined shape, thereby forming a photoresist 52, as illustrated in FIGS. 15(c) and 17(c). Next, the aluminum film 27 and the titanium film 26 are subjected to wet etching, dry etching (plasma etching) or an etching process of combination of such etching processes (for example, performing dry etching after wet etching) by using the photoresist 52, and moreover, the oxide semiconductor film 51 is subjected to wet etching. As illustrated in FIG. 15(d), part of the oxide semiconductor film 51, part of the titanium film 26, and part of the aluminum film 27 are removed, thereby forming an oxide semiconductor layer 13a, and a connection layer 25, and as illustrated in FIG. 17(d), a connection layer 38 is formed on a gate insulating layer 12, and moreover, a source line 16a formed by a multilayer film of a first conductive layer 14a and a second conductive layer 15a is formed on the connection layer 38.

In this case, as illustrated in FIG. 15(d), oxide semiconductor layer 13a and the connection layer 25 are integrally formed.

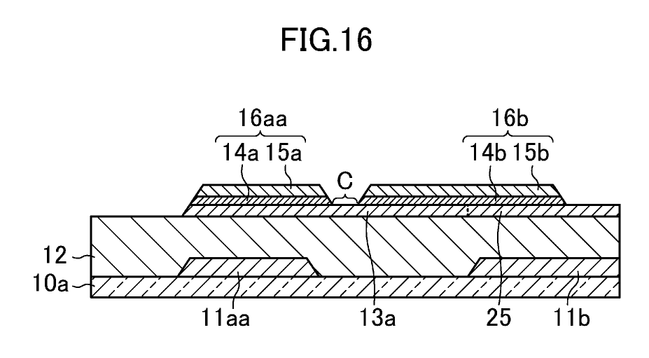

Next, as illustrated in FIGS. 15(e) and 17(e), the photoresist 52 is ashed to remove the photoresist in which the half exposure is performed. Then, by using the remaining photoresist 52, the titanium film 26 and the aluminum film 27 are subjected to dry etching, thereby forming a source electrode 16aa formed by a multilayer film of the first conductive layer 14a and the second conductive layer 15a on the oxide semiconductor layer 13a, as illustrated in FIG. 16, and forming the drain electrode 16b formed by a multilayer film of a first conductive layer 14b and a second conductive layer 15b on the connection layer 25 to expose a channel region C of the oxide semiconductor layer 13a.

In the foregoing manner, the semiconductor layer and connection layer formation step, and the source line and drain electrode formation step are performed with one photomask.

Thereafter, remove of the photoresist 52 and cleaning are performed, and then, as well as FIGS. 11(a)-11(d), and 13(a)-13(d) described in the above embodiment, the interlayer insulating film formation step, the planarization film formation step, the contact hole formation step, the pixel electrode and transparent conductive film formation step are performed, thereby fabricating the thin film transistor substrate. At this time, the fourth and fifth photomasks described in the above embodiment are used as third and fourth photomasks, and the thin film transistor is formed with four photomasks in total.

### INDUSTRIAL APPLICABILITY

The present invention is applicable to a display device substrate using a semiconductor layer of an oxide semiconductor, a method for fabricating the substrate, and a display device, for example.

### DESCRIPTION OF REFERENCE CHARACTERS

5a Thin film transistor

10a Insulating substrate

11a Gate line

11aa Gate electrode

11b Auxiliary Capacitor Line (Line Formed by Gate Line Layer)

12 Gate insulating layer

13a Oxide semiconductor layer

14a First conductive layer

14b First conductive layer

15a Second conductive layer

15b Second conductive layer

16a Source line

16aa Source electrode

16b Drain electrode

17 Interlayer insulating film

18 Planarization film

19a Pixel electrode

20 Thin film transistor substrate (display device substrate)

25 Connection layer

30 Counter substrate (another display device substrate)

38 Connection layer

40 Liquid crystal layer (display medium layer)

41 Transparent conductive film (conductive film)

50 Liquid crystal display device

C Channel region

Ca Contact hole

Cc Contact hole

1-10. (canceled)

11. A display device substrate, comprising:
an insulating substrate;
a gate insulating layer provided on the insulating substrate;
a connection layer provided on the gate insulating layer, and made of indium gallium zinc oxide;
a drain electrode provided on the connection layer, and made of titanium or a metal whose standard electrode potential is lower than that of titanium;
a contact hole formed in the connection layer and the drain electrode; and
a pixel electrode provided on a surface of the contact hole, and contacting the connection layer,
wherein
the drain electrode and the pixel electrode are electrically connected together through the connection layer.

12. The display device substrate of claim 11, wherein
the drain electrode includes a first conductive layer provided on a surface of the connection layer, and a second conductive layer provided on a surface of the first conductive layer, and
the first conductive layer is made of the titanium.

13. A display device substrate, comprising:
an insulating substrate;
a line provided on the insulating substrate, and formed by a gate line layer;
a gate insulating layer covering the line formed by the gate line layer;
a connection layer provided on the gate insulating layer, and made of indium gallium zinc oxide;
a line provided on the connection layer, and formed by a source line layer made of titanium or a metal whose standard electrode potential is lower than that of titanium;
a contact hole formed in the gate insulating layer, the connection layer, and the line formed by the source line layer; and
a conductive film provided on a surface of the contact hole, and contacting the line formed by the gate line layer and the connection layer,
wherein
the line formed by the gate line layer and the line formed by the source line layer are electrically connected together through the connection layer and the conductive film.

14. The display device substrate of claim 13, wherein
the line formed by the source line layer includes a first conductive layer provided on a surface of the connection layer, and a second conductive layer provided on a surface of the first conductive layer, and
the first conductive layer is made of the titanium.

15. A display device, comprising:
the display device substrate of claim 11;
another display device substrate provided to face the display device substrate; and
a display medium layer provided between the display device substrate and the another display device substrate.

16. The display device of claim 15, wherein
the display medium layer is a liquid crystal layer.

17. A display device, comprising:
the display device substrate of claim 13;
another display device substrate provided to face the display device substrate; and
a display medium layer provided between the display device substrate and the another display device substrate.

18. The display device of claim 17, wherein
the display medium layer is a liquid crystal layer.

19. A method for forming a display device substrate, the method comprising:
a gate insulating layer formation step of forming a gate insulating layer on an insulating substrate;
a connection layer formation step of forming, on the gate insulating layer, a connection layer made of indium gallium zinc oxide;
a drain electrode formation step of forming, on the connection layer, a drain electrode made of titanium or a metal whose standard electrode potential is lower than that of titanium;
a contact hole formation step of forming a contact hole in the connection layer and the drain electrode; and
a pixel electrode formation step of forming a pixel electrode on a surface of the contact hole to contact the connection layer, thereby electrically connecting the drain electrode and the pixel electrode together through the connection layer.

20. The method of claim 19, wherein
in the drain electrode formation step, a first conductive layer made of titanium is formed on a surface of the connection layer, and a second conductive layer is formed on the first conductive layer, thereby forming the drain electrode including a multilayer film of the first conductive layer and the second conductive layer.
